(19) United States
(12) Patent Application Publication
(10) Pub. No.: US 2025/0192039 A1
(43) Pub. Date: Jun. 12, 2025

(54) THREE-DIMENSIONAL MEMORY DEVICE AND MANUFACTURING METHOD THEREOF

(71) Applicant: SK hynix Inc., Icheon-si (KR)

(72) Inventors: Sung Lae OH, Icheon-si (KR); Sang Hyun SUNG, Icheon-si (KR)

(21) Appl. No.: 18/639,642

(22) Filed: Apr. 18, 2024

(30) Foreign Application Priority Data
Dec. 12, 2023 (KR) 10-2023-0179898

(51) Int. Cl. H01L 23/528; H10B 43/10; H10B 43/27

(52) U.S. Cl. CPC H01L 23/5283; H10B 43/10; H10B 43/27

(57) ABSTRACT

A three-dimensional memory device includes a stack including a plurality of electrode layers and a plurality of interlayer insulating layers which are alternately stacked on a substrate; a contact plug extending to one of the plurality of electrode layers by vertically penetrating the stack; and hard mask layers disposed between an upper portion of the contact plug and electrode layers around the upper portion of the contact plug.

### CROSS-REFERENCE TO RELATED APPLICATION

The present application claims priority under 35 U.S.C. § 119 (a) to Korean Patent Application No. 10-2023-0179898 filed in the Korean Intellectual Property Office on Dec. 12, 2023, which is incorporated herein by reference in its entirety.

### BACKGROUND

### 1. Technical Field

Various embodiments of the disclosed technology generally relate to a semiconductor technology, and particularly, to a three-dimensional memory device and a manufacturing method thereof.

### 2. Related Art

A three-dimensional memory device has advantages in that a larger capacity may be realized within the same area by increasing the number of stacks through vertically stacking memory cells, thereby providing high performance and excellent power efficiency.

In the three-dimensional memory device, electrode layers connected to the memory cells are disposed at different heights. In order to independently apply electrical signals to electrode layers disposed at different heights, contact plugs are connected to the respective electrode layers. To this end, a method of forming contact plugs extending to electrode layers by vertically penetrating a stack has been suggested.

### SUMMARY

Various embodiments of the disclosed technology are directed to a three-dimensional memory device with contact plugs that penetrate a stack and connect to electrode layers.

In an embodiment, a three-dimensional memory device may include: a stack including a plurality of electrode layers and a plurality of interlayer insulating layers, which are alternately stacked on a substrate; a contact plug extending to one of the plurality of electrode layers by vertically penetrating the stack; and hard mask layers disposed between an upper portion of the contact plug and electrode layers around the upper portion of the contact plug.

In an embodiment, a three-dimensional memory device may include: a stack including a plurality of electrode layers and a plurality of interlayer insulating layers, which are alternately stacked on a substrate; a first contact plug that vertically penetrates the stack and extends to one of the plurality of electrode layers; a second contact plug that vertically penetrates the stack and extends to another one of the plurality of electrode layers; first hard mask layers disposed between an upper portion of the first contact plug and electrode layers around the upper portion of the first contact plug; and second hard mask layers disposed between an upper portion of the second contact plug and electrode layers around the upper portion of the second contact plug, wherein the number of the first hard mask layers and the number of the second hard mask layers are not the same.

In an embodiment, a method for manufacturing a three-dimensional memory device may include: forming a pre-stack by alternately stacking a plurality of sacrificial layers and a plurality of interlayer insulating layers on a substrate; forming a pre-contact hole that penetrates an upper portion of the pre-stack; forming a plurality of horizontal grooves by removing sacrificial layers around the pre-contact hole; filling the horizontal grooves with hard mask layers; forming, on the pre-stack, a mask pattern that has an opening exposing the pre-contact hole; forming a contact hole by etching the pre-stack using the hard mask layers and the mask pattern as an etch mask; forming an insulating spacer on a side surface of the contact hole; forming a contact plug in the contact hole; and replacing the plurality of sacrificial layers with a plurality of electrode layers.

The insulating spacer comprises a first portion that is disposed on a side surface of an upper portion of the contact hole and a second portion that is disposed on a side surface of a lower portion of the contact hole, and the first portion is thicker than the second portion.

The mask pattern comprises photoresist.

According to the embodiments of the disclosed technology, it is possible to provide a three-dimensional memory device which has contact plugs connected to electrode layers by penetrating a stack.

### BRIEF DESCRIPTION OF THE DRAWINGS

FIG. 1 is a cross-sectional view of a three-dimensional memory device according to an embodiment of the disclosure.

FIGS. 2 and 3 are plan views of a connection region of a three-dimensional memory device according to an embodiment of the disclosure.

FIG. 4 is a cross-sectional view of a three-dimensional memory device according to an embodiment of the disclosure.

FIG. 5 is a flow chart showing a method for manufacturing a three-dimensional memory device according to an embodiment of the disclosure.

FIGS. 6 to 13 are cross-sectional views showing a method for manufacturing a three-dimensional memory device according to an embodiment of the disclosure.

### DETAILED DESCRIPTION

Hereinafter, embodiments of the present disclosure will be described in detail with reference to the accompanying drawings. In the following description, the same elements will be designated by the same reference numerals although they may be shown in different drawings. Further, in the following description of the present disclosure, a detailed description of known functions and configurations incorporated herein will be omitted when it may make the subject matter of the present disclosure rather unclear. It is to be understood that the terms “comprising,” “having,” “including” and so on, used in the description and claims, should not be interpreted as being restricted to the means listed thereafter unless specifically stated otherwise. Where an indefinite or definite article is used when referring to a singular noun, e.g., “a,” “an” and “the,” the singular noun may include a plural of that noun unless specifically stated otherwise.

Also, in describing the components of the disclosure, there may be terms used like first, second, A, B, (a), and (b). These are solely for the purpose of differentiating one component from another component but do not limit the substances, order, sequence or number of the components.

In descriptions for the positional relationships of components, where it is described that at least two components are “connected,” “coupled” or “linked,” it is to be understood that the at least two components may be directly “connected,” “coupled” or “linked” but components may also be indirectly “connected,” “coupled” or “linked” with another component interposed between the two components. Here, another component may be included in at least one of the at least two components which are “connected,” “coupled” or “linked” with each other.

In descriptions of relationships of components, an operating method or a fabricating method with respect to the flow of time, “pre” and “post” relationships in terms of time or “pre” and “post” relationships in terms of flow are described, such as for example using terms “after,” “following,” “next” or “before”. Non-continuous cases may be included unless “immediately” or “directly” is used.

Where a numerical value for a component or its corresponding information is used, even though there is no separate explicit description, the numerical value or its corresponding information can be interpreted as including an error range related to various factors (for example, a process variable, an internal or external shock, noise, etc.).

Hereinafter, various embodiments of the disclosed technology will be described in detail with reference to the accompanying drawings.

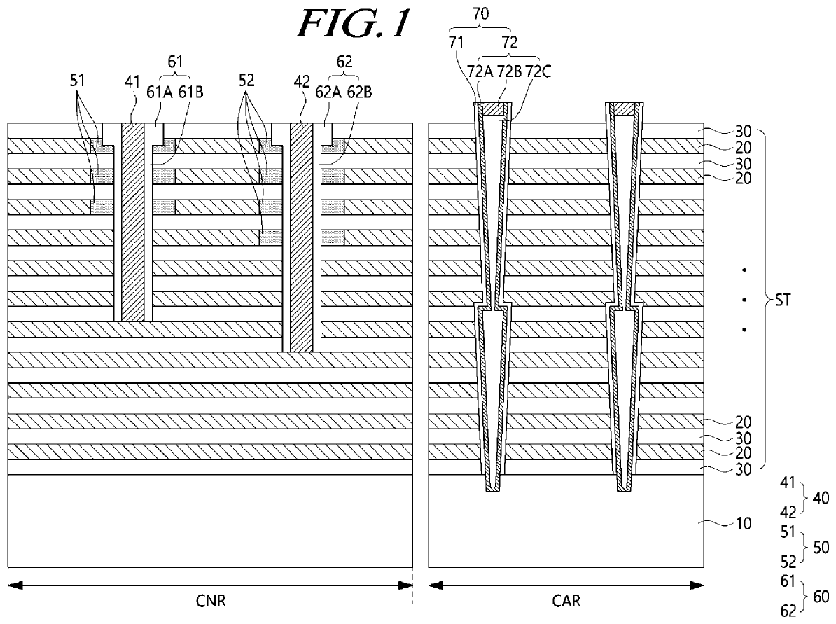

FIG. 1 is a cross-sectional view of a three-dimensional memory device according to an embodiment of the disclosure.

As illustrated in FIG. 1, a stack ST is disposed in a connection region CNR and a cell array region CAR of a substrate 10.

The stack ST may include a plurality of electrode layers 20 and a plurality of interlayer insulating layers 30, which are alternately stacked. The electrode layers 20 may include a conductive material. For example, the electrode layers 20 may include at least one selected from among a doped semiconductor (e.g., doped silicon), a metal (e.g., tungsten, copper or aluminum), a conductive metal nitride (e.g., titanium nitride or tantalum nitride) and a transition metal (e.g., titanium or tantalum). The interlayer insulating layers 30 may include oxide.

The electrode layers 20 may configure row lines. The row lines may include at least one source select line, at least one drain select line, and a plurality of word lines. Among the electrode layers 20, at least one electrode layer 20 from a lowermost electrode layer 20 may configure a source select line, and at least one electrode layer 20 from an uppermost electrode layer 20 may configure a drain select line. The electrode layers 20 between the source select line and the drain select line may configure word lines.

Contact plugs 40 may vertically penetrate through the stack ST in the connection region CNR. Each contact plug 40 may extend to one of the plurality of electrode layers 20 by vertically penetrating the stack ST from the upper surface of the stack ST, and may be electrically connected to the one electrode layer 20.

The contact plugs 40 may include a first contact plug 41 and a second contact plug 42, which are connected to different electrode layers 20. For the sake of simplicity in illustration, FIG. 1 illustrates only two contact plugs 40 connected to two electrode layers 20. However, a plurality of contact plugs 40 may be provided in correspondence to the plurality of electrode layers 20, respectively, and each contact plug 40 may be electrically connected to a corresponding electrode layer 20.

Hard mask layers 50 may be disposed around the upper portions of the contact plugs 40. The hard mask layers 50 may include first hard mask layers 51, which are disposed around the upper portion of the first contact plug 41, and second hard mask layers 52, which are disposed around the upper portion of the second contact plug 42.

The first hard mask layers 51 may be disposed between the upper portion of the first contact plug 41 and electrode layers 20, which are arranged around the upper portion of the first contact plug 41. The second hard mask layers 52 may be disposed between the upper portion of the second contact plug 42 and electrode layers 20, which are arranged around the upper portion of the second contact plug 42.

The first hard mask layers 51 may serve as an etch barrier in an etching process for forming a contact hole, which provides a space for disposing the first contact plug 41. The second hard mask layers 52 may serve as an etch barrier in an etching process for forming a contact hole, which provides a space for disposing the second contact plug 42. The first and second hard mask layers 51 and 52 may be formed of a material that has an etch selectivity different from that of the interlayer insulating layers 30. For example, the first and second hard mask layers 51 and 52 may be formed of an insulating material, which has an etch selectivity different from that of the interlayer insulating layers 30.

Depending on the depth to which a contact plug 40 penetrates the stack ST, the number of hard mask layers disposed around the contact plug 40 may vary. A depth to which the second contact plug 42 penetrates the stack ST may be greater than a depth to which the first contact plug 41 penetrates the stack ST, and the number of the second hard mask layers 52 that are disposed around the second contact plug 42 may be greater than the number of the first hard mask layers 51 that are disposed around the first contact plug 41.

Insulating spacers 60 may be disposed on the side surfaces of the contact plugs 40. The insulating spacers 60 may include a first insulating spacer 61, which is disposed on side surfaces of the first contact plug 41 and a second insulating spacer 62, which is disposed on side surfaces of the second contact plug 42.

The first insulating spacer 61 may surround side surfaces of the first contact plug 41. The first insulating spacer 61 may isolate the first contact plug 41 and the stack ST from each other, and may isolate the first contact plug 41 and the first hard mask layers 51 from each other.

The second insulating spacer 62 may surround side surfaces of the second contact plug 42. The second insulating spacer 62 may isolate the second contact plug 42 and the stack ST from each other, and may isolate the second contact plug 42 and the second hard mask layers 52 from each other. The first and second insulating spacers 61 and 62 may include oxide.

The first insulating spacer 61 may include a first portion 61A, which is connected to the upper surface of the stack ST, and a second portion 61B, which is disposed under the first portion 61A and has a wall thickness that is thinner than the first portion 61A. The second insulating spacer 62 may include a first portion 62A, which is connected to the upper surface of the stack ST and a second portion 62B, which is disposed under the first portion 62A and has a wall thickness that is thinner than the first portion 62A.

The wall thickness of the first hard mask layers 51 may vary depending on the wall thickness of the first insulating spacer 61. For example, a portion of a first hard mask layer 51 common to the first portion 61A of the first insulating spacer 61 may have a wall thickness that is thinner than a portion of the first hard mask layer 51 common to the second portion 61B of the first insulating spacer 61.

The wall thickness of the second hard mask layers 52 may vary depending on the wall thickness of the second insulating spacer 62. For example, a portion of a second hard mask layer 52 common to the first portion 62A of the second insulating spacer 62 may have a wall thickness that is thinner than a portion of the second hard mask layer 52 common to the second portion 62B of the second insulating spacer 62.

A plurality of cell plugs 70 may vertically pass through the stack ST in the cell array region CAR and extend into the substrate 10. Each cell plug 70 may include a memory pattern 71 and a channel structure 72.

Although not illustrated, the memory pattern 71 may include a tunnel insulating layer, a data storage layer and a first blocking insulating layer. The tunnel insulating layer may extend along the surface of the channel structure 72, and may include an insulating material capable of charge tunneling. The data storage layer may extend along the surface of the channel structure 72 with the tunnel insulating layer interposed therebetween. The data storage layer may include a material layer capable of storing data that may be changed using Fowler-Nordheim tunneling. For example, the data storage layer may include a nitride layer capable of charge trapping, but examples are not limited thereto. The data storage layer may include a phase change material, nanodots, etc. The first blocking insulating layer may extend along the surface of the channel structure 72 with the tunnel insulating layer and the data storage layer interposed therebetween. The first blocking insulating layer may include an insulating material capable of blocking the movement of charges.

The channel structure 72 may include a cell channel layer 72A, a capping pattern 72B and a core insulating pattern 72C. The cell channel layer 72A is used as the channel of a memory cell string. The cell channel layer 72A is disposed on the memory pattern 71, and may be formed of a semiconductor material. For example, the cell channel layer 72A may include silicon. The capping pattern 72B and the core insulating pattern 72C may fill the central region of the channel structure 72. The core insulating pattern 72C may include oxide. The capping pattern 72B may be disposed on the core insulating pattern 72C, and may include a sidewall that is surrounded by the upper end portion of the cell channel layer 72A. The capping pattern 72B may include a doped semiconductor layer that includes at least one of an n-type impurity and a p-type impurity.

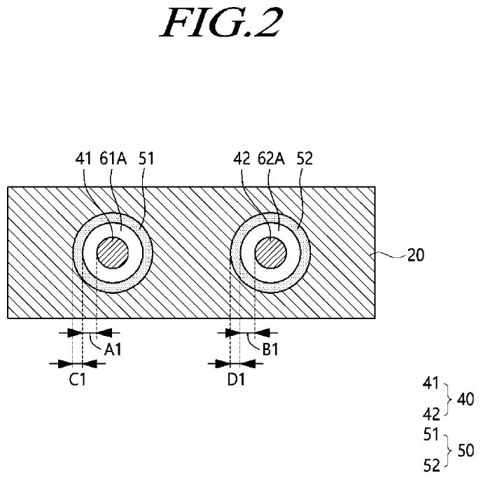

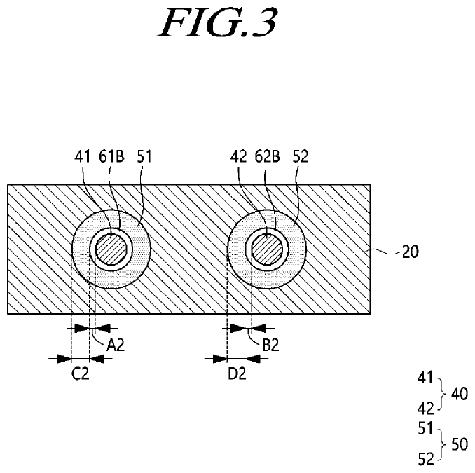

FIGS. 2 and 3 are plan views of a connection region of a three-dimensional memory device according to an embodiment of the disclosure. FIG. 2 is a layout view of a plane including first portions 61A and 62A of first and second insulating spacers 61 and 62, and FIG. 3 is a layout view of a plane including second portions 61B and 62B of first and second insulating spacers 61 and 62.

Referring to FIGS. 2 and 3, a first insulating spacer 61 may surround a side surface of a first contact plug 41. The first insulating spacer 61 may have a ring shape and may surround a side surface of the first contact plug 41. An inner surface of the first insulating spacer 61 may contact a side surface of the first contact plug 41.

A first hard mask layer 51 may surround an outer surface of the first insulating spacer 61. The first hard mask layer 51 may have a ring shape and may surround an outer surface of the first insulating spacer 61.

The first portion 61A of the first insulating spacer 61 and the second portion 61B of the first insulating spacer 61 may have different wall thicknesses. For example, the first portion 61A of the first insulating spacer 61 may have a thickness of A1, and the second portion 61B of the first insulating spacer 61 may have a thickness of A2, which is smaller than A1.

A second insulating spacer 62 may surround a side surface of a second contact plug 42. The second insulating spacer 62 may have a ring shape that surrounds the side surface of the second contact plug 42. An inner surface of the second insulating spacer 62 may contact the side surface of the second contact plug 42. A second hard mask layer 52 may surround an outer surface of the second insulating spacer 62. The second hard mask layer 52 may have a ring shape and may surround an outer surface of the second insulating spacer 62.

The first portion 62A of the second insulating spacer 62 and the second portion 62B of the second insulating spacer 62 may have different wall thicknesses. For example, the first portion 62A of the second insulating spacer 62 may have a thickness of B1, and the second portion 62B of the second insulating spacer 62 may have a thickness of B2, which is smaller than B1.

Referring to FIG. 2, a portion of the first hard mask layer 51 may be disposed on the same plane as the first portion 61A of the first insulating spacer 61 and may be disposed to have a thickness of C1.

Referring to FIG. 3, a portion of the first hard mask layer 51 may be disposed on the same plane as the second portion 61B of the first insulating spacer 61 and may be disposed to have a thickness of C2. Wall thickness C1 may be different from wall thickness C2, and in an example, thickness C2 is larger than C1.

Referring to FIG. 2, a portion of the second hard mask layer 52 may be disposed on the same plane as the first portion 62A of the second insulating spacer 62 and may be disposed to have a thickness of D1. Referring to FIG. 3, a portion of the second hard mask layer 52 may be disposed on the same plane as the second portion 62B of the second insulating spacer 62 and may be disposed to have a thickness of D2. Wall thickness D1 may be different from wall thickness D2, and in an example, thickness D2 is larger than D1.

In FIG. 1, the first portion 61A of the first insulating spacer 61 and the first portion 62A of the second insulating spacer 62 have the same height, but embodiments of the disclosed technology are not limited thereto. For example, the first portion 61A of the first insulating spacer 61 and the first portion 62A of the second insulating spacer 62 may have different heights.

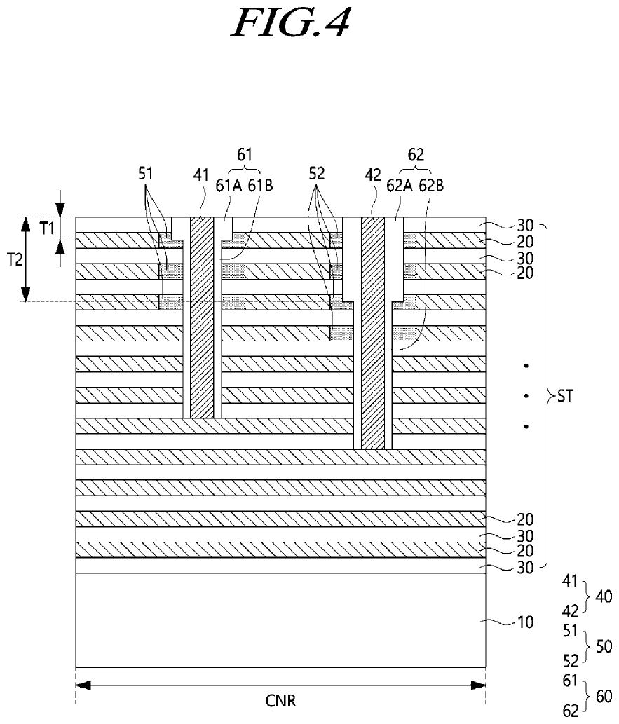

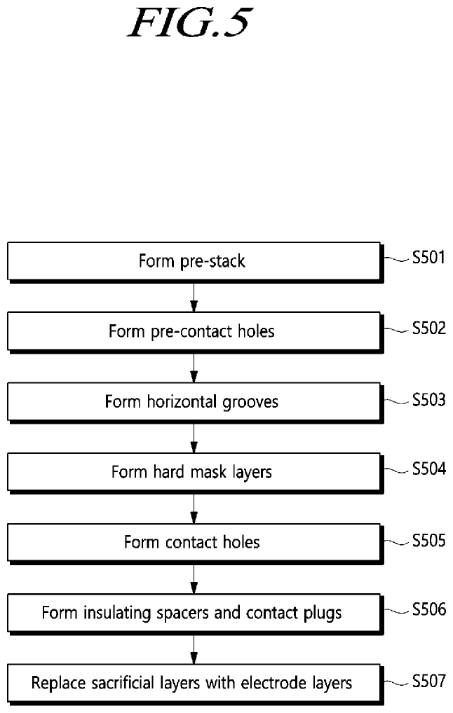

FIG. 4 is a cross-sectional view of a three-dimensional memory device according to an embodiment of the disclosure.

Referring to FIG. 4, a first portion 61A of a first insulating spacer 61 may have a first height T1, and a first portion 62A of a second insulating spacer 62 may have a second height T2, which is greater than the first height T1.

The first portion 61A of the first insulating spacer 61 may be disposed above a lower surface of a lowermost first hard mask layer 51 among the first hard mask layers 51. The distance between the first portion 61A of the first insulating spacer 61 and the substrate 10 may be larger than the distance between the lowermost first hard mask layer 51 and the substrate 10.

The first portion 62A of the second insulating spacer 62 may be disposed above the lower surface of a lowermost second hard mask layer 52 among the second hard mask layers 52. The distance between the first portion 62A of the second insulating spacer 62 and the substrate 10 may be larger than the distance between the lowermost second hard mask layer 52 and the substrate 10.

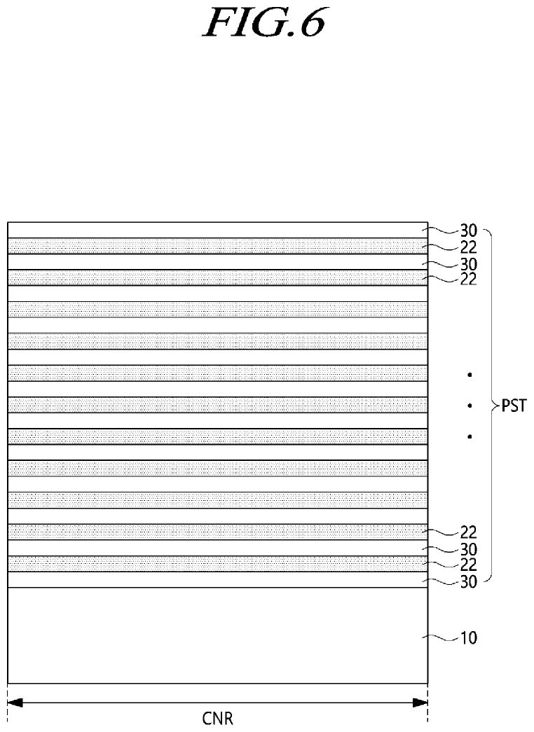

FIG. 5 is a flow chart showing a method for manufacturing a three-dimensional memory device according to an embodiment of the disclosure, and FIGS. 6 to 13 are cross-sectional views showing a method for manufacturing a three-dimensional memory device according to an embodiment of the disclosure.

Referring to FIGS. 5 and 6, a step of forming a pre-stack PST is performed (S501).

The pre-stack PST is formed by alternately stacking a plurality of sacrificial layers 22 and a plurality of interlayer insulating layers 30 on a substrate 10. The interlayer insulating layers 30 may include oxide such as silicon oxide. The sacrificial layers 22 may include a material that has an etch selectivity different from that of the interlayer insulating layers 30, for example, a nitride such as silicon nitride.

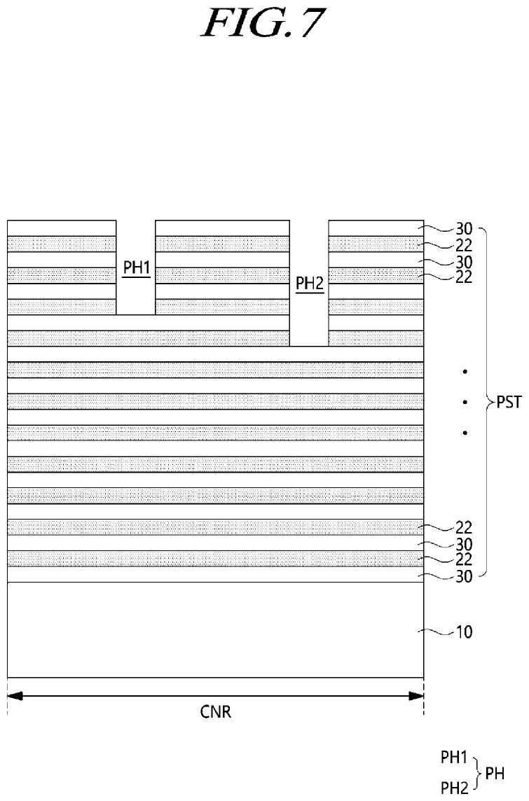

Referring to FIGS. 5 and 7, a step of forming pre-contact holes PH is performed (S502).

A process of forming a pre-contact hole PH may include forming, on the pre-stack PST, a mask pattern (not illustrated), which exposes an area where the pre-contact hole PH is to be formed, and etching the pre-stack PST using the mask pattern as an etch mask.

The pre-contact holes PH may be formed at different depths. The pre-contact holes PH with different depths may be formed through different processes. By repeating the process of forming a pre-contact hole PH, the pre-contact holes PH with different depths may be formed.

The pre-contact holes PH may include a first pre-contact hole PH1 and a second pre-contact hole PH2 that have different depths. The first pre-contact hole PH1 may extend to one of the plurality of interlayer insulating layers 30, and the second pre-contact hole PH2 may extend to another one of the plurality of interlayer insulating layers 30. Although only two pre-contact holes PH are illustrated in the drawing for the sake of simplicity in illustration, but two or at least three pre-contact holes PH with different depths may be formed.

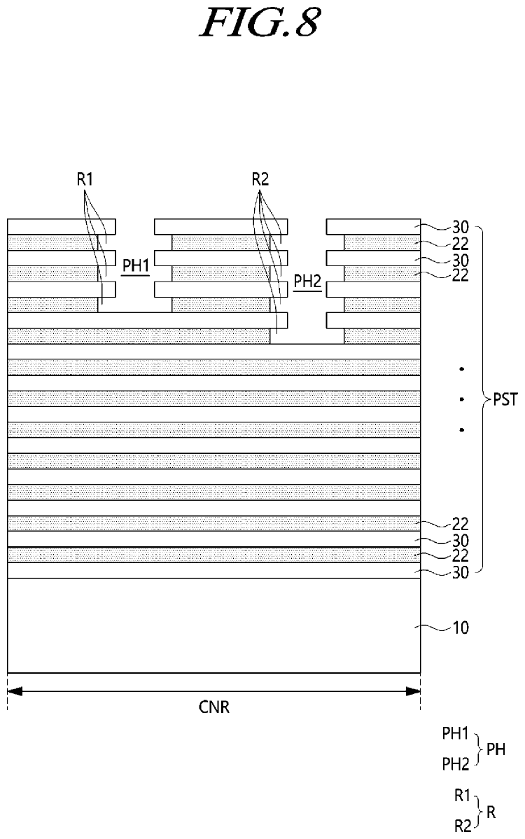

Referring to FIGS. 5 and 8, a step of forming horizontal grooves R is performed (S503).

The horizontal grooves R may be formed by selectively removing sacrificial layers 22, which are exposed by the pre-contact holes PH. As a process for forming the horizontal grooves R, an isotropic etching process using an etchant capable of selectively removing the sacrificial layers 22 may be used. The horizontal grooves R may include first horizontal grooves R1 that communicate with the first pre-contact hole PH1 and second horizontal grooves R2 that communicate with the second pre-contact hole PH2.

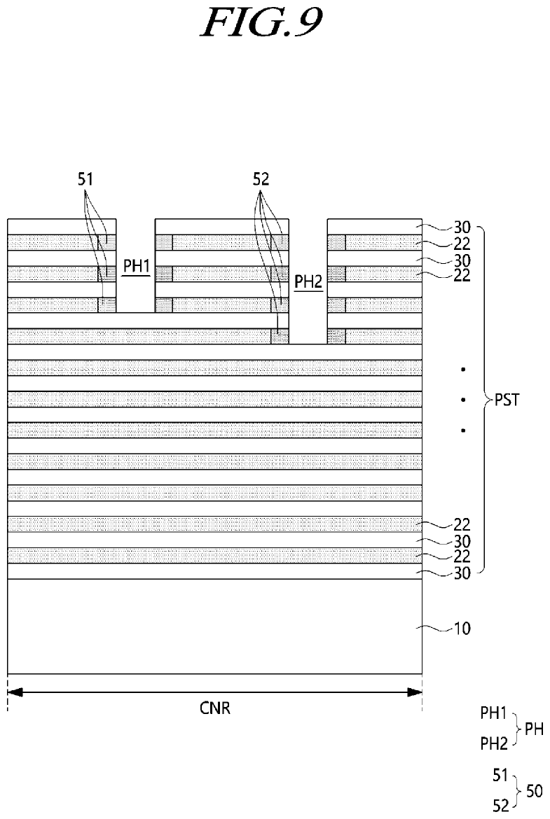

Referring to FIGS. 5 and 9, a step of forming hard mask layers 50 in the horizontal grooves R is performed (S504).

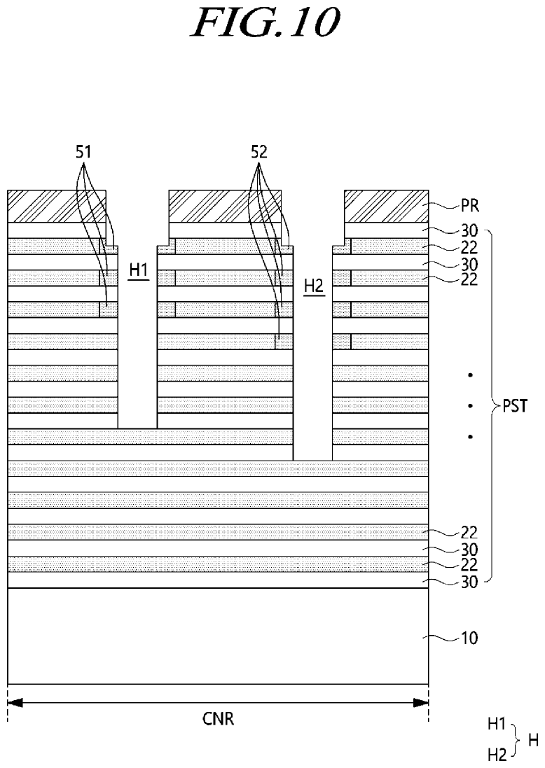

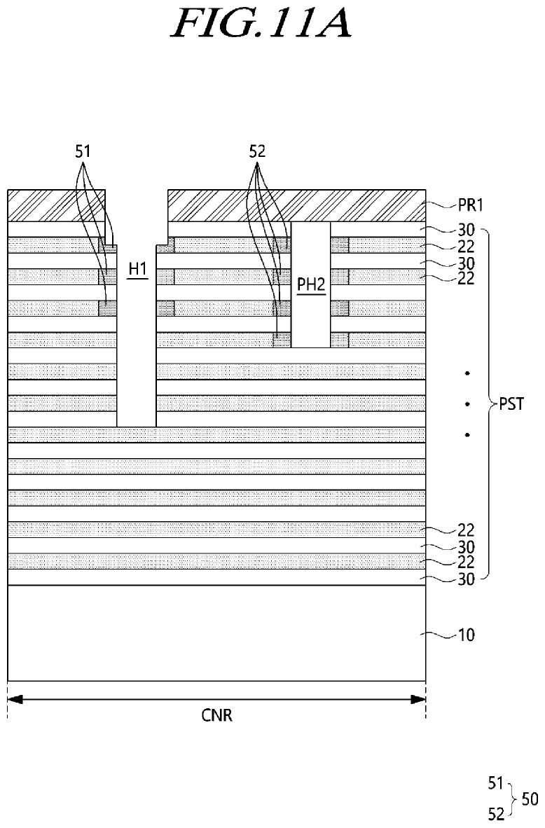

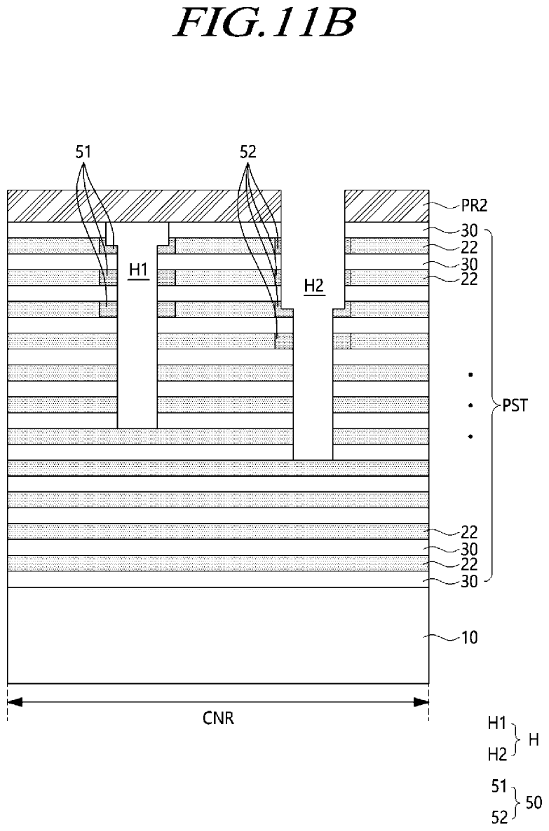

By forming a hard mask layer to fill the horizontal grooves R and removing the hard mask layer formed outside the horizontal grooves R, the horizontal grooves R may be filled with the hard mask layers 50. The hard mask layers 50 may include first hard mask layers 51, which fill the first horizontal grooves R1, and second hard mask layers 52, which fill the second horizontal grooves R2. The hard mask layers 50 may include a material that has an etch selectivity different from those of the plurality of sacrificial layers 22 and the plurality of interlayer insulating layers 30. The hard mask layers 50 may serve as an etch mask or an etch barrier in an etching process for forming contact holes H to be described below with reference to FIGS. 10, 11A and 11B.

Referring to FIGS. 5 and 10, a step of forming contact holes H is performed (S505).

By forming a mask pattern PR having openings that expose the first and second pre-contact holes PH1 and PH2, and by etching the pre-stack PST using the mask pattern PR and the first and second hard mask layers 51 and 52 as etch masks, first and second contact holes H1 and H2 may be formed.

The openings of the mask pattern PR may expose not only the first and second pre-contact holes PH1 and PH2 but also the pre-stack PST around the first and second pre-contact holes PH1 and PH2. In the etching process, the first hard mask layers 51 common to the first pre-contact hole PH1, and the interlayer insulating layers 30 between the first hard mask layers 51 and common to the first pre-contact hold PH1, may be etched. The second hard mask layers 52 common to the second pre-contact hole PH2, and the interlayer insulating layers 30 between the second hard mask layers 52 and common to the second pre-contact hole PH2, may be etched. Accordingly, the upper portion of the first contact hole H1 may have a dimension (e.g., width or diameter) larger than that of the lower portion of the first contact hole H1, and the upper portion of the second contact hole H2 may have a dimension larger than that of the lower portion of the second contact hole H2.

Since the first hard mask layers 51 serve as an etch barrier in the etching process, the upper portion of the first contact hole H1, which has a larger dimension, may be disposed above the lower surface of a lowermost first hard mask layer 51. Since the second hard mask layers 52 serve as an etch barrier in the etching process, the upper portion of the second contact hole H2, which has a larger dimension, may be disposed above the lower surface of a lowermost second hard mask layer 52.

Since the first and second contact holes H1 and H2 are formed through a single etching process using a single mask pattern, the upper portion of the first contact hole H1 with a larger dimension and the upper portion of the second contact hole H2 with a larger dimension may have the same depth as each other.

The mask pattern PR may be formed of photoresist, and the mask pattern PR remaining after the etching process may be removed through a strip process.

FIG. 10 illustrates a first contact hole H1 and a second contact hole H2 formed through a single etching process. However, as will be described below with reference to FIGS. 11A and 11B, the first contact hole H1 and the second contact hole H2 may be formed through separate etching processes using separate mask patterns.

Referring to FIG. 11A, by forming a mask pattern PR1, which covers the second pre-contact hole PH2 and has an opening exposing the first pre-contact hole PH1, and by etching the pre-stack PST using the mask pattern PR1 and the first hard mask layers 51 as an etch mask, a first contact hole H1 is formed.

The opening of the mask pattern PR1 may expose not only the first pre-contact hole PH1 but also the pre-stack PST around the first pre-contact hole PH1. During the etching process, the first hard mask layers 51 around the first pre-contact hole PH1 and the interlayer insulating layers 30 between the first hard mask layers 51 may be etched. Accordingly, the upper portion of the first contact hole H1 may have a larger dimension than the lower portion of the first contact hole H1. Since the first hard mask layers 51 serve as an etch barrier in the etching process, the upper portion of the first contact hole H1, which has a larger dimension, may be disposed above the lower surface of a lowermost first hard mask layer 51.

The mask pattern PR1 may be formed of photoresist, and the mask pattern PR1 remaining after the etching process may be removed through a strip process.

Referring to FIG. 11B, by forming a mask pattern PR2 that covers the first contact hole H1 and has an opening exposing the second pre-contact hole PH2, and by etching the pre-stack PST using the mask pattern PR2 and the second hard mask layers 52 as an etch mask, a second contact hole H2 that is deeper than the first contact hole H1 is formed.

The opening of the mask pattern PR2 may expose not only the second pre-contact hole PH2 but also the pre-stack PST around the second pre-contact hole PH2. During the etching process, the second hard mask layers 52 around the second pre-contact hole PH2 and the interlayer insulating layers 30 between the second hard mask layers 52 may be etched. Accordingly, the upper portion of the second contact hole H2 may have a larger dimension than the lower portion of the second contact hole H2.

Since the second hard mask layers 52 serve as an etch barrier in the etching process, the upper portion of the second contact hole H2, which has a larger dimension, may be disposed above the lower surface of a lowermost second hard mask layer 52.

The mask pattern PR2 may be formed of photoresist, and the mask pattern PR2 remaining after the etching process may be removed through a strip process.

Since the hard mask layers 50 are disposed between the interlayer insulating layers 30 of the pre-stack PST, the etching process for forming the contact holes H may be easily performed. Elaborating on this, since the hard mask layers 50 are disposed between the interlayer insulating layers 30 of the pre-stack PST, when compared to a case where a hard mask layer is disposed on the pre-stack PST, a distance to an etch target may decrease, and thus, the difficulty of an etching process may be reduced and the etching process may be easily performed.

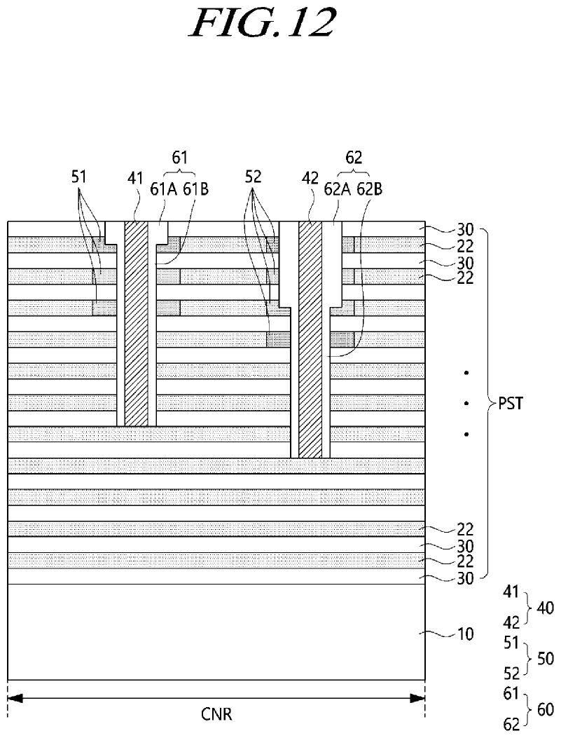

Referring to FIGS. 5 and 12, a step of forming insulating spacers 60 and contact plugs 40 is performed (S506).

By forming an insulating layer on the entire surface including the contact holes H, and by etching the insulating layer so that portions of the insulating layer remain on the side surfaces of the contact holes H, the insulating spacers 60 may be formed. The insulating spacers 60 include a first insulating spacer 61, which is formed on the side surface of the first contact hole H1, and a second insulating spacer 62, which is formed on the side surface of the second contact hole H2.

The first insulating spacer 61 includes a first portion 61A, which is formed on the side surface of the upper portion of the first contact hole H1 having a larger dimension, and a second portion 61B under the first portion 61A. The second insulating spacer 62 includes a first portion 62A, which is formed on the side surface of the upper portion of the second contact hole H2 having a larger dimension, and a second portion 62B under the first portion 62A.

The first portion 61A of the first insulating spacer 61 may be formed to a thickness thicker than that of the second portion 61B of the first insulating spacer 61. The first portion 62A of the second insulating spacer 62 may be formed to a thickness thicker than that of the second portion 62B of the second insulating spacer 62.

Thereafter, by filling the central regions of the contact holes H with a conductive material, the contact plugs 40 are formed.

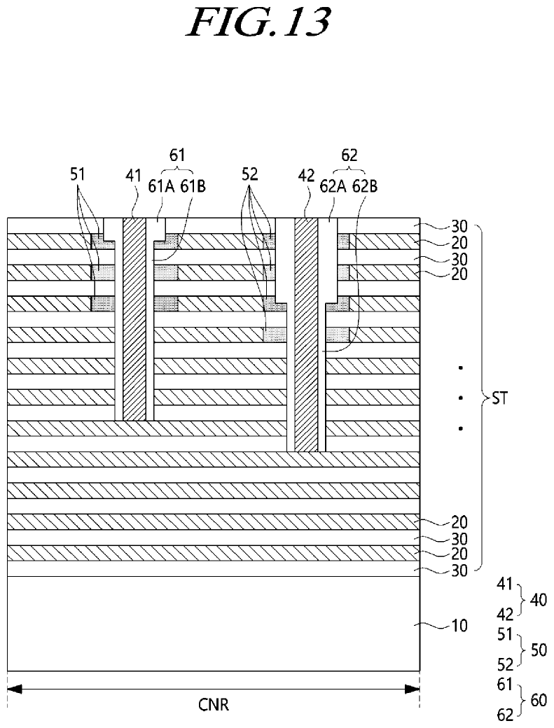

Referring to FIGS. 5 and 13, a step of replacing the sacrificial layers 22 with electrode layers 20 is performed (S507).

By selectively removing the sacrificial layers 22 and filling empty regions created by removal of the sacrificial layers 22 with an electrode material, the electrode layers 20 are formed. Although not illustrated, before forming the electrode layers 20, a blocking insulating layer may be additionally formed on the surfaces of empty regions created by removal of the sacrificial layers 22.

Although exemplary embodiments of the present disclosure have been described for illustrative purposes, those skilled in the art will appreciate that various modifications, additions and substitutions are possible, without departing from the scope and spirit of the present disclosure. Therefore, the embodiments disclosed above and in the accompanying drawings should be considered in a descriptive sense only and not for limiting the technological scope. The technological scope of the present disclosure is not limited by the embodiments and the accompanying drawings.

What is claimed is:

1. A three-dimensional memory device comprising:
a stack including a plurality of electrode layers and a plurality of interlayer insulating layers, which are alternately stacked on a substrate;
a contact plug extending to one of the plurality of electrode layers by vertically penetrating the stack; and
hard mask layers disposed between an upper portion of the contact plug and electrode layers around the upper portion of the contact plug.

2. The three-dimensional memory device according to claim 1, wherein each of the hard mask layers has a ring shape that surrounds the contact plug.

3. The three-dimensional memory device according to claim 1, wherein the hard mask layers comprise a material that has an etch selectivity different from that of the plurality of interlayer insulating layers.

4. The three-dimensional memory device according to claim 1, further comprising:
an insulating spacer disposed on a side surface of the contact plug,
wherein the insulating spacer comprises:
a first portion connected to an upper surface of the stack; and
a second portion under the first portion, and
wherein the first portion is thicker than the second portion.

5. The three-dimensional memory device according to claim 4, wherein a portion of a hard mask layer that faces the first portion of the insulating spacer has a thickness thinner than that of a portion of the hard mask layer that faces the second portion of the insulating spacer.

6. The three-dimensional memory device according to claim 4, wherein the insulating spacer comprises oxide.

7. The three-dimensional memory device according to claim 4, wherein the first portion of the insulating spacer is disposed above a lower surface of a lowermost hard mask layer.

8. A three-dimensional memory device comprising:
a stack including a plurality of electrode layers and a plurality of interlayer insulating layers, which are alternately stacked on a substrate;
a first contact plug that vertically penetrates the stack and extends to one of the plurality of electrode layers;
a second contact plug that vertically penetrates the stack and extends to another one of the plurality of electrode layers;
first hard mask layers disposed between an upper portion of the first contact plug and electrode layers around the upper portion of the first contact plug; and
second hard mask layers disposed between an upper portion of the second contact plug and electrode layers around the upper portion of the second contact plug,
wherein the number of the first hard mask layers and the number of the second hard mask layers are not the same.

9. The three-dimensional memory device according to claim 8, further comprising:
a first insulating spacer surrounding a side surface of the first contact plug; and
a second insulating spacer surrounding a side surface of the second contact plug,
wherein each of the first and second insulating spacers comprises:
a first portion connected to an upper surface of the stack; and
a second portion disposed under the first portion, and
wherein the first portion is thicker than the second portion.

10. The three-dimensional memory device according to claim 9, wherein
a portion of a first hard mask layer that faces the first portion of the first insulating spacer is thinner than a portion of the first hard mask layer that faces the second portion of the first insulating spacer, and
a portion of a second hard mask layer that faces the first portion of the second insulating spacer is thinner than a portion of the second hard mask layer that faces the second portion of the second insulating spacer.

11. The three-dimensional memory device according to claim 9, wherein the distance between the first portion of the first insulating spacer and the substrate is different from the distance between the first portion of the second insulating spacer and the substrate.

12. The three-dimensional memory device according to claim 9, wherein
the first portion of the first insulating spacer is disposed above a lower surface of a lowermost first hard mask layer, and
the first portion of the second insulating spacer is disposed above a lower surface of a lowermost second hard mask layer.

13. The three-dimensional memory device according to claim 9, wherein the first and second insulating spacers comprise oxide.

14. The three-dimensional memory device according to claim 8, wherein
each of the first hard mask layers has a ring shape that surrounds the first contact plug, and
each of the second hard mask layers has a ring shape that surrounds the second contact plug.

15. The three-dimensional memory device according to claim 8, wherein the first and second hard mask layers comprise a material that has an etch selectivity different from that of the plurality of interlayer insulating layers.

16. A method for manufacturing a three-dimensional memory device, comprising:
forming a pre-stack by alternately stacking a plurality of sacrificial layers and a plurality of interlayer insulating layers on a substrate;
forming a pre-contact hole that penetrates an upper portion of the pre-stack;
forming a plurality of horizontal grooves by removing sacrificial layers around the pre-contact hole;
filling the horizontal grooves with hard mask layers;
forming, on the pre-stack, a mask pattern that has an opening exposing the pre-contact hole;
forming a contact hole by etching the pre-stack using the hard mask layers and the mask pattern as an etch mask;
forming an insulating spacer on a side surface of the contact hole;
forming a contact plug in the contact hole; and
replacing the plurality of sacrificial layers with a plurality of electrode layers.

17. The method according to claim 16, wherein the hard mask layers comprise a material that has an etch selectivity different from those of the plurality of sacrificial layers and the plurality of interlayer insulating layers.

18. The method according to claim 16, wherein the plurality of horizontal grooves are formed by isotropically etching sacrificial layers exposed by the pre-contact hole.

19. The method according to claim 16, wherein the opening of the mask pattern is formed to expose the pre-contact hole and the pre-stack around the pre-contact hole.

20. The method according to claim 16, wherein in the forming of the contact hole, at least a portion of the hard mask layers around the pre-contact hole and a portion of interlayer insulating layers disposed alternately with the hard mask layers is removed.
